(19) United States
(12) Patent Application Publication
(10) Pub. No.: US 2007/0108463 A1
(43) Pub. Date: May 17, 2007

(54) Light-emitting diode with UV-blocking nano-particles

(76) Inventors: Janet Bee Yin Chua, Perak (MY); Yue Hoong Lau, Penang (MY)

Correspondence Address: AGILENT TECHNOLOGIES INC., INTELLECTUAL PROPERTY ADMINISTRATION,LEGAL DEPT., MS BLDG. E P.O. BOX 7599, LOVELAND, CO, 80537, US

(21) Appl. No.: 11/283,026

(22) Filed: Nov. 17, 2005

(51) Int. Cl. H01L 33/00

(52) U.S. Cl. 257/100

(57) ABSTRACT

A light-emitting device has an encapsulated light-emitter. Nano-particles substantially transparent to visible light block UV light.

### CROSS-REFERENCE TO RELATED APPLICATIONS

Not applicable.

### STATEMENT REGARDING FEDERALLY SPONSORED RESEARCH OR DEVELOPMENT

Not applicable.

### REFERENCE TO MICROFICHE APPENDIX

Not applicable.

### BACKGROUND OF THE INVENTION

Packaged light-emitting diodes (“LEDs” or “LED lamps”) typically have encapsulant dispensed onto or molded around an LED chip mounted on a header and electrically connected to leads with one or more wire bonds. The encapsulant is usually a transparent polymer, such as an epoxy or silicone, that protects the LED chip and wire bond from mechanical and environmental damage while allowing light emitted by the LED chip to pass through with minimal loss. A dispersant is sometimes added to the encapsulant to promote diffusion of the light if the light is to be used in an instrument panel.

Some LEDs are intended to be used outdoors, such as in outdoor signage. Such devices typically do not include dispersant, and emit visible light. However, ultra-violet (“UV”) light from sunshine is absorbed by conventional polymeric encapsulant, causing degradation of the encapsulant (typically yellowing and clouding) and reduced light extraction from the LED chip, undesirably altering the light emitted by the device. Extensive, prolonged exposure of an LED device to UV light often leads to catastrophic failure. Reduced light extraction, in turn, leads to more UV absorption, often leading to catastrophic failure of the light-emitting device.

Therefore, LEDs that resist degradation from external UV light are desired.

### BRIEF SUMMARY OF THE INVENTION

A light-emitting device has an encapsulated light-emitter. Nano-particles substantially transparent to visible light block UV light.

### BRIEF DESCRIPTION OF THE DRAWINGS

FIG. 1 shows a cross section of an LED lamp according to an embodiment of the invention.

FIG. 2 shows a cross section of an LED lamp according to another embodiment of the invention.

FIG. 3 shows a cross section of an LED lamp according to yet another embodiment of the invention.

### DETAILED DESCRIPTION OF THE EMBODIMENTS

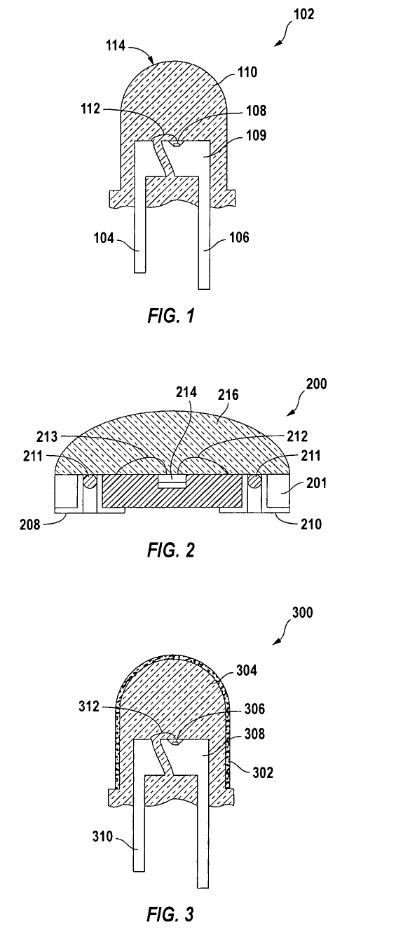

FIG. 1 shows an LED lamp 102 according to an embodiment of the invention. Leads 104, 106 have been cut from a lead frame, as is well known in the art of LED manufacturing. One lead 104 has been cut shorter than the other lead 106 to indicate the electrical polarity of the LED chip 108. One lead 106 includes a header 109 on which the LED chip 108 is mounted, frequently in a reflective cup. Encapsulant 110 secures one lead relative to the other to prevent avoid damage to the bond wire 112.

The encapsulant is made from transparent polymer, such as epoxy, silicone, polymethylmethacrylate (PMMA”), or a combination of polymers, such as a silicone-epoxy hybrid system, or other plastic(s) and is cast or molded around the LED chip. The encapsulant 110 is often shaped to form a lens 114 that facilitates a desired pattern of light extracted from the LED chip 108. In particular, the LED chip 108 produces an essentially point-source of light, and the lens 114 makes the LED lamp 102 appear more uniformly illuminated.

The encapsulant 110 includes UV-blocking nano-particles. The UV-blocking nano-particles are particles of one or more materials, such as silica (SiO₂), alumina (Al₂O₃), titania (TiO₂), having a particle size less than 100 nm. The UV-blocking nano-particles absorb UV light and reduce degradation of the encapsulant from ambient UV light, such as solar UV light when the LED lamp is used in an outdoor application.

In a particular embodiment, Al₂O₃, SiO₂ and TiO₂ nano-particles were used in an encapsulant formulation. Approximately 16.7 weight % nano-alumina provides suitable protection from UV radiation while allowing transmission of visible light. However, such a concentration of nano-alumina creates stress in both epoxy-based and silicone-based encapsulation systems, which can lead to de-bonding of the bond wire or cracking of the LED die. Approximately 3.5 weight percent to about 5 weight percent of nano-titania is added to an epoxy-based encapsulant formulation to lower the stresses generated by thermal cycling. Stress reductions between 80% and 60% were observed. Nano-silica was added to the encapsulant formulation to increase the glass transition temperature (“TG”) of an epoxy-based encapsulant system. The optimal amount of nano-silica depends on the heat generated by the LED die and the maxium ambient temperature.

A typical operating temperature specification for an LED device is −40 degrees Celsius to 120 degrees Celsius. Generally, an LED chip will heat up during operation, and will heat the encapsulant around it, which is a particular problem for “high-power” LED devices (generally, devices that are driven at more than about 20 mA). An encapsulated LED chip driven at 20 mA or more can achieve a temperature at its surface of approximately 120-130 degrees Celsius, which exceeds the TG of conventional LED encapsulants. Nano-silica between about 12.5 weight percent to about 20 weight percent added to an epoxy-based encapsulant formulation desirably increases TG to about 140 degrees Celsius.

Adding nano-alumina to conventional liquid encapsulant precursor materials (e.g. liquid (uncured) epoxy resin) increases the viscosity of the encapsulant precursor formulation. If nano-titania or nano-silica is added, the encapsulant precursor will be thickened further. When using encapsulant precursor formulations according to embodiments, it is often desirable to use a resin with lower viscosity, so that the encapsulant precursor formulation will have a resultant viscosity close to conventional encapsulant precursors. In a particular embodiment, about 16.7 weight percent nano-alumina, about 5 weight percent nano-titania, and about 12 weight percent nano-silica were added to a liquid epoxy encapsulant precursor having an initial viscosity of about 400 centipoise (“cps”). The resultant encapsulant formulation had a viscosity of about 800 cps, which was suitable for use in a conventional LED encapsulating process. Encapsulant formulations with a resultant viscosity of between about 800 CPS and about 3000 cps are suitable for use in conventional LED encapsulation apparatus. Generally, the initial viscosity of the encapsulant predursor, whether it is a liquid epoxy resin or other liquid precursor, is selected so that the resultant viscosity of the encapsulant formulation, after mixing with nano-particles, is suitable for use in the LED encapsulation apparatus, in other words, between about 800 cps and about 3000 cps.

Elastomer-based (e.g. silicone-based) encapsulants generate less thermal stress at the die/wire bond. Nano-titania may be omitted in some embodiments. Some elastomer-based encapsulants also have a higher TG than conventional epoxy encapsulants, and nano-silica may also be omitted in some embodiments.

The UV-blocking nano-particles effectively absorb UV light (generally light having a wavelength less than about 380 nm to about 10 nm; however, solar UV light is typically divided in to UVA, which is light between 380-315 nm, and UVB, which is light between 315-280 nm), while not significantly absorbing (blocking) the visible light that is desired to be extracted from the LED chip 108. It is particularly desirable to avoid drive current degradation in LED devices used in outdoor applications, such as automotive or signage applications, where the allowable degradation of I_{V} is not more than −15%, whereas the allowable degradation of I_{V} for some indoor applications is not more than −35%.

FIG. 2 shows a cross section of an LED lamp 200 according to another embodiment of the invention. An LED chip 214 is attached to a PCB substrate 201. Bond wires 212, 213 electrically couple terminals (not shown) on the LED chip 214 to terminals 208, 210 on the PCB substrate 201. The terminals 208, 210 are plated through holes that allow surface mounting of the light source 200 on a surface-mount circuit substrate. The plated through holes are plugged with a compound 211, such as solder resist, before encapsulant containing UV-blocking nano-particles 216 shaped as a dome is molded over the LED chip 214 and top of the PCB substrate 201.

FIG. 3 shows a cross section of an LED lamp 300 according to yet another embodiment of the invention. A coating 302 of UV-blocking nano-particles is disposed on the encapsulant 304 of the lamp. The encapsulant 304 is conventional encapsulant. In a particular embodiment, the coating 302 contains at least about 8 weight percent, generally between about 8 weight percent and about 17 weight percent, and in a particular embodiment, about 16.7 weight percent nano-alumina in an epoxy resin. The encapsulant 304 is a similar epoxy resin, and the thermal expansion coefficient of the coating is sufficiently similarly to the thermal expansion coefficient of the encapsulant so as to avoid delamination over the operating temperature range and lifetime of the device.

In a particular embodiment, the LED chip 306 is mounted to the header 308 and connected to the lead 310 with the bond wire 312. The lead and header are typically part of a lead-frame, as are well known in the art of LED lamp fabrication. Conventionally, the LED assembly is inserted into a mold cup, which is filled with liquid encapsulant precursor (e.g. epoxy resin) and cured. The mold cup is basically the negative of the desired final shape/size of the LED lamp. For example, if a 5 mm LED lamp is desired, a 5 mm mold cup is used.

In a particular embodiment according to FIG. 3, the LED assembly is first inserted into a mold cup with a reduced diameter. For example, if a 5 mm LED with a 0.5 mm coating 302 thickness is desired, a 4 mm mold cup is used to first encapsulate the LED assembly. Then, the encapsulated LED assembly is inserted into a second mold cup having the final desired diameter (i.e. 5 mm) that has a measured amount of UV-blocking coating precursor. The UV-blocking coating precursor surrounds the encapsulated LED assembly and is cured to form the LED lamp 300. Although this approach adds a second mold cup sequence, it is easily incorporated into an existing mold cup encapsulation line. Furthermore, using the same system (e.g. epoxy-based) for the encapsulant and for the UV-blocking coating 302 is conveniently incorporated into an existing encapsulation process. Alternatively, the UV-blocking coating is formed first, and provides a hard shell into which encapsulant 304 is dispensed and the LED assembly is encapsulated in.

Since the coating 302 blocks UV, nano-alumina may be omitted from the encapsulant 304 in some embodiments. In such case, nano-titania may also be omitted because the nano-alumina-related stress does not arise. Nano-silica is optionally included in the encapsulant 304 to increase TG.

Alternatively, the encapsulant includes UV-blocking nano-particles. In a particular embodiment, the LED chip emits UV light that is converted into visible light by a wavelength-converting (e.g. phosphor) coating, such as a phosphor coating that converts UV light to blue light. Degradation of the encapsulant may occur from unconverted UV light produced by the LED chip. Thus, in some embodiments, it is also desirable to include UV-blocking nano particles in the encapsulant 304, as well as in the coating 302. However, if the coating sufficiently blocks solar UV, the amount of nano-alumina in the encapsulant is reduced to between about 5 weight percent and about 10 weight percent. In some embodiments, the concentration of nano-alumina in the encapsulant is sufficiently low to avoid excessive stress, and nano-titania is omitted from the encapsulant formulation. Nano-silica is optionally included in the encapsulant to increase TG. Nano-alumina is omitted from the encapsulant formulation if it is desired to transmit UV light from the LED chip 306 through the encapsulant 304.

Alternatively, the coating 302 includes nano-alumina dispersed in a carrier, such as a water-based acrylic, polyurethane, or benzophenone carrier, that is applied to the encapsulated LED assembly and cured. The nano-alumina is in sufficient concentration to block solar UV from degrading the LED lamp. Applying the UV-blocking nano-particles in a water-based coating is particularly desirable when applying nano-particles provided in an aqueous solution or gel. Generally, organic molecules in the water-based carrier polymerize into a transparent water-proof film that adheres well to the encapsulant 304 and blocks between about 70% and about 90% of sloar UV light from entering the encapsulant.

Alternatively, the LED lamp is dipped into a heated solution containing UV-blocking nano-particles. Pores in the encapsulant open in response to the heat of the solution, and UV-blocking nano particles, either with or without residual solution, are incorporated into a “skin layer” of the encapsulant. In a particular embodiment, the LED lamp is dipped into a heated solution of benzophenone containing nano-alumina particles.

While the preferred embodiments of the present invention have been illustrated in detail, it should be apparent that modifications and adaptations to these embodiments might occur to one skilled in the art without departing from the scope of the present invention as set forth in the following claims.

What is claimed is:

1. A light-emitting device having:
encapsulant;
a light-emitter within the encapsulant; and
UV-blocking nano-particles substantially transparent to visible light.

2. The light-emitting device of claim 1 wherein the UV-blocking nano-particles comprise nano-alumina.

3. The light-emitting device of claim 1 wherein the UV-blocking nano-particles are incorporated in a layer disposed on the encapsulant.

4. The light-emitting device of claim 3 wherein the layer comprises nano-alumina comprises between about 8 weight percent and about 17 weight percent in an epoxy resin.

5. The light-emitting device of claim 4 wherein the encapsulant comprises the epoxy resin.

6. The light-emitting device of claim 5 wherein the encapsulant further comprises between about 5 weight percent and about 10 weight percent nano-alumina.

7. The light emitting device of claim 5 wherein the encapsulant further comprises nano-silica.

8. The light-emitting device of claim 1 wherein the UV-blocking nano-particles are disposed in the encapsulant.

9. The light-emitting device of claim 8 wherein the UV-blocking nano-particles comprise between about 8 weight percent and about 17 weight percent nano-alumina in a liquid encapsulant precursor material to provide an encapsulant formulation.

10. The light-emitting device of claim 9 wherein the liquid encapsulant precursor is an elastomeric resin.

11. The light-emitting device of claim 9 wherein the liquid encapsulant precursor is an epoxy resin.

12. The light-emitting device of claim 11 wherein the encapsulant formulation further comprises between about 3.5 weight percent and about 5 weight percent nano-titania.

13. The light-emitting device of claim 11 wherein the encapsulant formulation further comprises between about 12.5 weight percent and about 20 weight percent nano-silica.

14. The light-emitting device of claim 11 wherein the epoxy resin has an initial viscosity less than about 800 centipoise.

15. The light-emitting device of claim 1 wherein the light emitter is an LED.

16. The light-emitting device of claim 15 wherein the LED has an operating current of at least 20 mA.

17. The light-emitting device of claim 15 wherein the LED emits UV light.
